(19) United States
(12) Patent Application Publication
(10) Pub. No.: US 2025/0076345 A1
(43) Pub. Date: Mar. 6, 2025

(54) CURRENT SENSOR-ATTACHED TERMINAL BLOCK

(71) Applicant: Yazaki Corporation, Tokyo (JP)

(72) Inventors: Akinori SAKAMOTO, Makinohara-shi (JP); Yoshio SUGIMOTO, Makinohara-shi (JP)

(73) Assignee: Yazaki Corporation, Tokyo (JP)

(21) Appl. No.: 18/782,790

(22) Filed: Jul. 24, 2024

(30) Foreign Application Priority Data
Aug. 29, 2023 (JP) 2023-138780

(51) Int. Cl. G01R 15/18; G01R 19/00

(52) U.S. Cl. CPC G01R 15/183; G01R 19/0092

(57) ABSTRACT

A current sensor-attached terminal block includes a busbar in a plate shape, a current sensor configured to detect a current flowing through the busbar, a housing holding the busbar and the current sensor, and attached to an attachment hole of a casing of an electronic device, a first ring-shaped seal member, and a second ring-shaped seal member, wherein a first connection portion on one end side of the busbar and a second connection portion on the other end side of the busbar are exposed outside the housing, and a middle portion of the busbar is situated inside the housing, the first ring-shaped seal member is attached to an outer peripheral portion of the middle portion of the busbar to seal between busbar and the housing, and the second ring-shaped seal member is attached to an outer peripheral portion of the housing to seal between the housing and the attachment hole.

### TECHNICAL FIELD

The present disclosure relates to a current sensor-attached terminal block in which a terminal block for connecting wiring and a current sensor are integrated.

### BACKGROUND

A conventional terminal block 501 illustrated in FIG. 10 (see Patent Document 1) is fixed to a casing of a traction motor mounted on an automobile, and includes three busbars 503, a collar 515, and a housing 502 that holds them.

Each of the busbars 503 has a first connection portion 531 on one end side, and a second connection portion 532 on the other end side. The first connection portion 531 has a bolt insertion hole 531a formed therein. The terminal of the motor is placed on the first connection portion 531, and the terminal and the first connection portion 531 are fastened together with a bolt and a nut to make an electrical connection between the first connection portion 531 and the terminal of the motor. The second connection portion 532 is in electrical connection with a terminal of the inverter.

The housing 502 includes a flange portion 521 that holds the collar 515, and a busbar holding portion 522 that is connected to the flange portion 521 and holds middle portions of the busbars 503. The flange portion 521 is placed on the casing of the motor, and the busbar holding portion 522 is threaded through an attachment hole in the casing. A bolt is passed through the collar 515 and a nut is screwed onto the bolt, thereby fixing the terminal block 501 to the casing of the motor.

In this way, the terminal block 501 electrically connects the terminals of the motor and the terminals of the inverter. The current between the inverter and the motor is monitored by a current sensor and a control unit, and is controlled to a predetermined current value. The current sensor is provided separately from the terminal block 501 and is provided in the inverter or the motor.

### RELATED ART

### Patent Documents

[Patent Document 1] JP2022003619 A

### SUMMARY OF THE INVENTION

### Problem to be Solved by the Invention

As described above, in the conventional technique, the terminal block and the current sensor are provided separately, and the inverter or the motor including them is large.

It is an object of the present invention to provide a current sensor-attached terminal block that allows for reduction of an electronic device in size.

### Solution to Problem

According to an aspect of the present disclosure, a current sensor-attached terminal block includes a busbar in a plate shape, a current sensor configured to detect a current flowing through the busbar, a housing holding the busbar and the current sensor, and attached to an attachment hole of a casing of an electronic device, a first ring-shaped seal member, and a second ring-shaped seal member, wherein a first connection portion on one end side of the busbar and a second connection portion on the other end side of the busbar are exposed outside the housing, and a middle portion of the busbar is situated inside the housing, the first ring-shaped seal member is attached to an outer peripheral portion of the middle portion of the busbar to seal between busbar and the housing, and the second ring-shaped seal member is attached to an outer peripheral portion of the housing to seal between the housing and the attachment hole.

### Advantageous Effects of the Invention

A current sensor-attached terminal block according to an aspect of the present disclosure integrated with a terminal block and a current sensor takes up less mounting space than a case where a terminal block and a current sensor are separately provided, thus allowing for reduction of electronic devices in size.

### BRIEF DESCRIPTION OF THE DRAWINGS

FIG. 1 is a perspective view of a current sensor-attached terminal block according to one embodiment of the present invention.

FIG. 2 is a perspective view of the current sensor-attached terminal block of FIG. 1 as seen from a different angle.

FIG. 3 is a plan view of the current sensor-attached terminal block of FIG. 1.

FIG. 4 is a front view of the current sensor-attached terminal block of FIG. 1.

FIG. 5 is a rear view of the current sensor-attached terminal block of FIG. 1.

FIG. 6 is a side view of the current sensor-attached terminal block of FIG. 1.

FIG. 7 is a cross-sectional view taken along line A-A of FIG. 3.

FIG. 8 illustrates the current sensor-attached terminal block of FIG. 1 attached to an attachment hole of a casing of an electronic device.

FIG. 9 is an explanatory diagram explaining the configuration of the current sensor of FIG. 1.

FIG. 10 is a perspective view of a conventional terminal block.

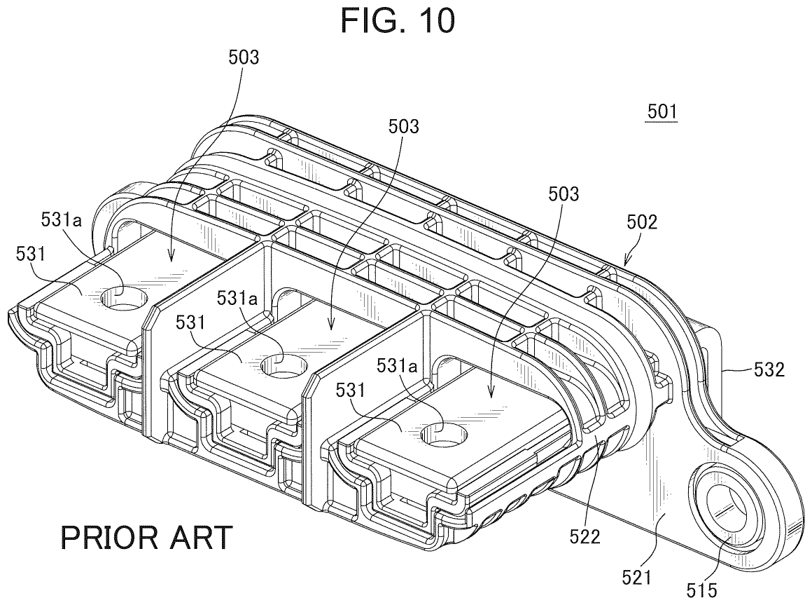

### DETAILED DESCRIPTION OF THE EXEMPLARY EMBODIMENT

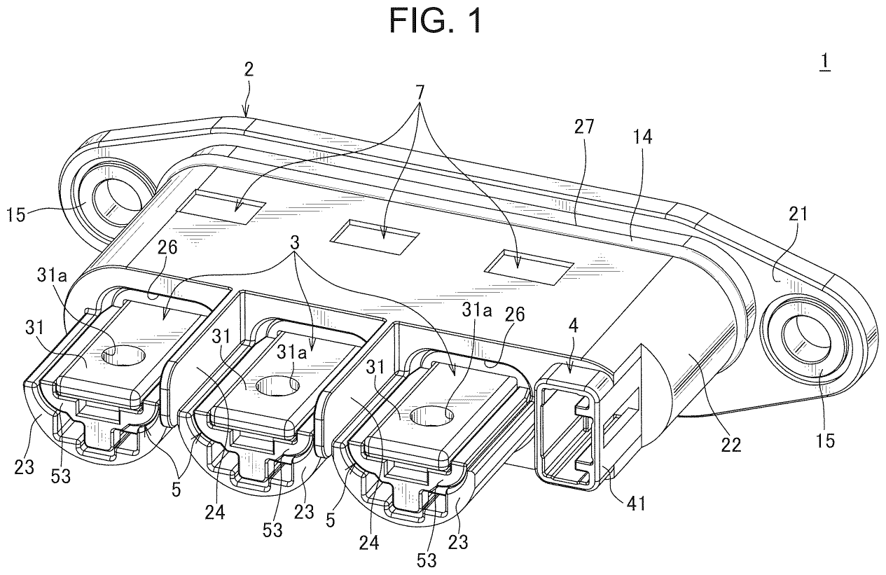

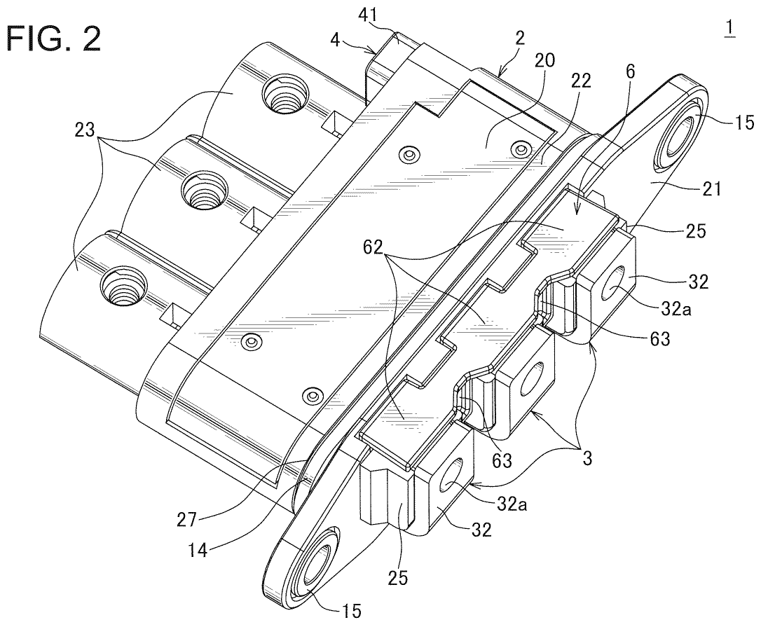

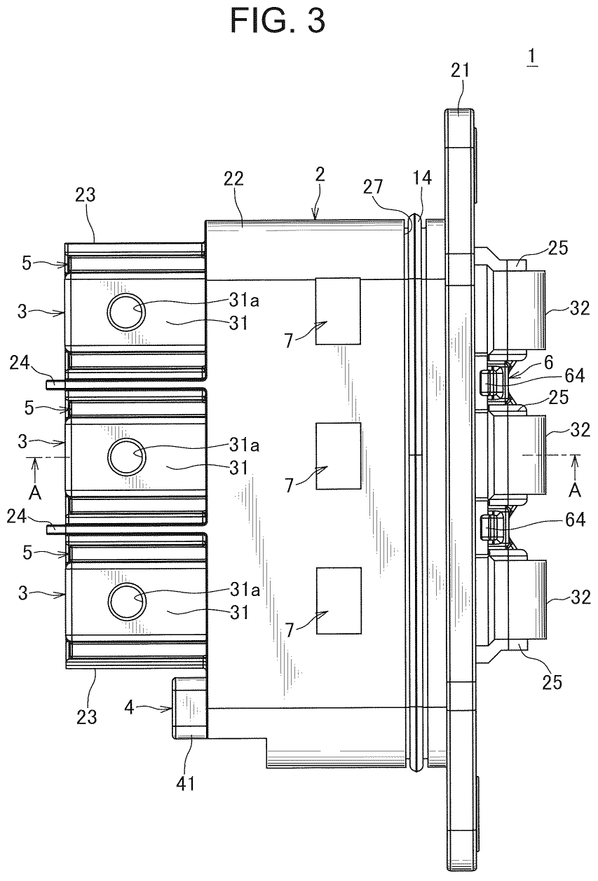

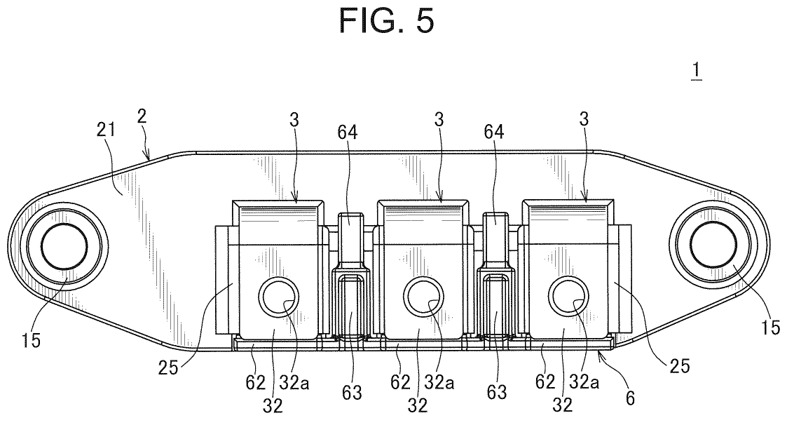

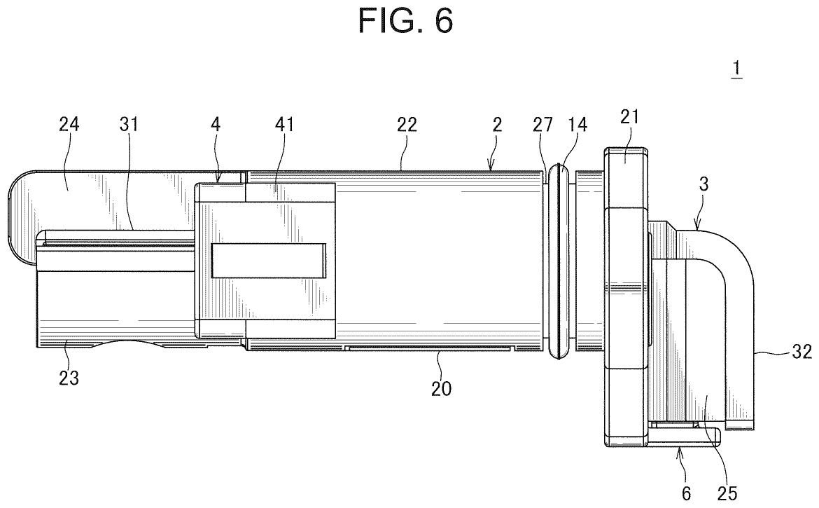

A “current sensor-attached terminal block” 1 according to one embodiment of the present invention is described with reference to FIGS. 1 to 9.

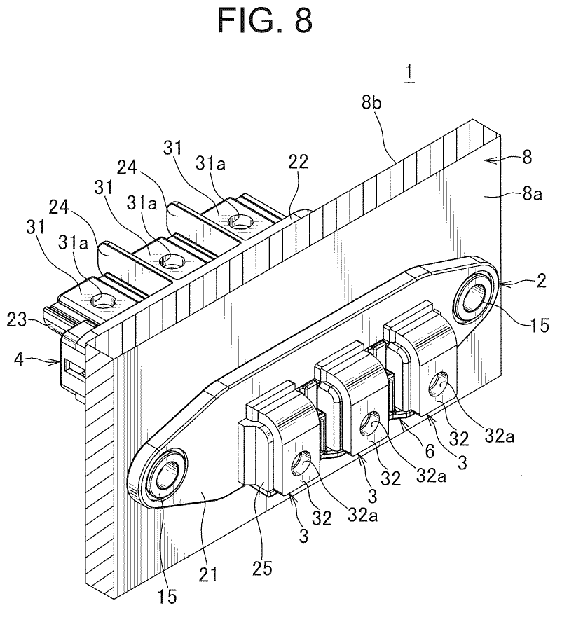

The current sensor-attached terminal block 1 illustrated in FIGS. 1 to 7 is used as a component of an “e-Axle” and is attached to an attachment hole of a casing 8 of the e-Axle as illustrated in FIG. 8. The e-Axle is an integrated unit of a motor, an inverter, and a transmission, and is mounted in automobiles using the motor as the main power source. In FIG. 8, one surface 8a of the casing 8 faces the motor room, and the other side 8b faces the inverter room.

The current sensor-attached terminal block 1 includes busbars 3, current sensors 7, circuit boards 16, a connector portion 4, a housing 2, a cover 20, collars 15, first nuts 11, first nut holders 5, second nuts 12, a second nut holder 6, first ring-shaped seal members 13, and a second ring-shaped seal member 14.

The busbar 3 is obtained by applying press processing to a metal plate. In this example, the busbar 3 is a long, thin strip of metal plate bent at a right angle in one place, forming an L-shape overall. The current sensor-attached terminal block 1 includes three busbars 3 of the same configuration and size.

One end of the busbar 3 is a first connection portion 31, and the other end is a second connection portion 32. A middle portion 33 of the busbar 3 is positioned within the housing 2. The first connection portion 31 and the second connection portion 32 are exposed to the outside of the housing 2. The first connection portion 31 and the middle portion 33 are connected flush with each other. The boundary between the second connection portion 32 and the middle portion 33 is bent at a right angle. The first connection portion 31 and the second connection portion 32 have bolt insertion holes 31a and 32a formed therein, respectively.

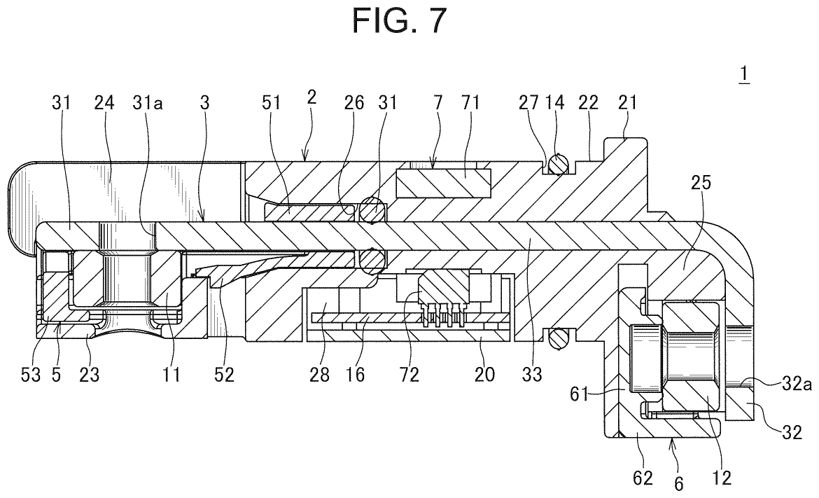

As illustrated in FIG. 8, the first connection portion 31 is disposed in the inverter chamber, and the inverter terminals are placed thereon. The first connection portions 31 and the inverter terminals placed thereon are electrically connected by fastening them together with a bolt and a first nut 11. As illustrated in FIG. 7, the first nut 11 is placed on the first connection portion 31 with the bolt hole of the first nut 11 overlapping with the bolt insertion hole 31a. A bolt insertion hole overlapping with the bolt insertion hole 31a is formed in the terminal of the inverter, and a bolt is passed through the bolt insertion hole of the inverter and the bolt insertion hole 31a, so that the bolt is screwed into the first nut 11.

As illustrated in FIG. 8, the second connection portion 32 is disposed in the motor chamber and the motor terminal is placed on the second connection portion 32. The second connection portion 32 and the motor terminal placed thereon are electrically connected by fastening them together with a bolt and a second nut 12. As illustrated in FIG. 7, the second nut 12 is placed on the second connection portion 32 with the bolt hole of the second nut 12 overlapping with the bolt insertion hole 32a. A bolt insertion hole overlapping with the bolt insertion hole 32a is formed in the terminal of the motor, and a bolt is passed through the bolt insertion hole of the motor and the bolt insertion hole 32a, so that the bolt is screwed into the second nut 12.

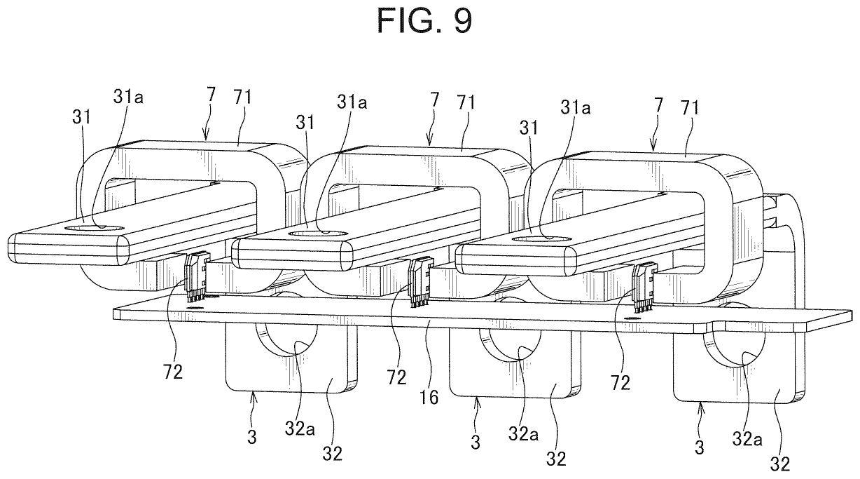

Three current sensors 7 in total are provided, and each of the current sensors 7 is provided for the corresponding busbar 3 to detect the current flowing through the busbar 3. As illustrated in FIGS. 7 and 9, each of the current sensors 7 includes a C-shaped magnetic core 71 surrounding the middle portion 33 of the busbar 3, and a detection element 72 disposed in the gap of the magnetic core 71. The detection elements 72 are mounted on the circuit boards 16.

When a current flows from the inverter to the motor via the busbar 3, a magnetic flux proportional to the current is generated in magnetic core 71. The detection element 72 converts the magnetic flux generated in the magnetic core 71 into a voltage. The output voltage of the detection element 72 is output to a control unit via the circuit board 16, the connector portion 4, wiring connected to the connector portion 4, and the like.

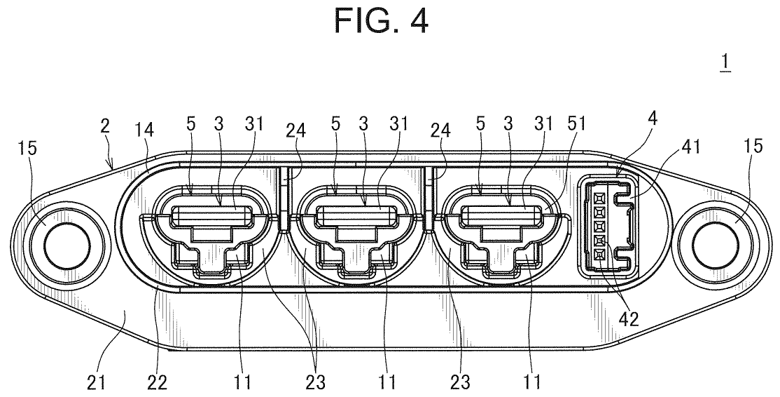

As illustrated in FIG. 4, the connector portion 4 includes a plurality of terminals 42 and a housing portion 41 that holds the plurality of terminals 42. The plurality of terminals 42 are electrically connected to the circuit boards 16.

The housing 2 is made of insulating synthetic resin. The housing 2 integrally includes a flange portion 21, a main body portion 22, first nut holder holding portions 23, partition walls 24, and second nut holder holding portions 25.

The flange portion 21 is formed in a plate shape and holds two collars 15. As illustrated in FIG. 8, the flange portion 21 is placed on one surface 8a of the casing 8. Then, bolts are passed through the collars 15 and nuts are screwed onto the bolts, thereby fixing the current sensor-attached terminal block 1 to the casing 8.

The main body portion 22 protrudes from one surface of the flange portion 21. The middle portion 33 of the busbar 3 and the magnetic core 71 are embedded in the main body portion 22 and are integrated with the main body portion 22. The main body portion 22 is formed with accommodation spaces 28 that accommodate the detection elements 72 and the circuit boards 16, recesses 26 that accommodate the first ring-shaped seal members 13, and an annular groove 27 in which the second ring-shaped seal member 14 is attached. The main body portion 22 is passed through an attachment hole of the casing 8.

The accommodation space 28 is open in one direction, and the detection element 72 and the circuit board 16 are housed in the accommodation space 28 through this opening. This opening is closed by the cover 20.

The recesses 26 is formed concavely from the end face of the main body portion 22 away from the flange portion 21 toward the flange portion 21. Three recesses 26 are formed. One end of each of the busbars 3 passes through the corresponding recess 26 and is exposed outside the main body portion 22 (outside the housing 2). The other end of each of the busbars 3 passes through the flange portion 21 and is exposed outside the housing 2.

Three first ring-shaped seal members 13 in total are provided, and each of the first ring-shaped seal members 13 is provided for a corresponding one of the busbars 3. The first ring-shaped seal member 13 is attached to the outer peripheral portion of the middle portion 33 of the busbar 3 to seal between the outer peripheral portion of the busbar 3 and the inner peripheral portion of the recess 26.

The annular groove 27 is formed in the outer peripheral portion of the main body portion 22. The annular groove 27 is also formed in the vicinity of the flange portion 21. The second ring-shaped seal member 14 attached to the annular groove 27 seals between the outer peripheral portion of the main body portion 22 and the inner peripheral portion of the attachment hole of the casing 8.

The current sensor-attached terminal block 1 can be used in environments where it is exposed to oil because the first ring-shaped seal member 13 and the second ring-shaped seal member 14 function as an oil-proof structure.

Three first nut holder holding portions 23 are provided. The first nut holder holding portions 23 extend from the end face of the main body portion 22 away from the flange portion 21 to the opposite side to the flange portion 21. Each of the first nut holder holding portions 23 is provided in the vicinity of the corresponding one of the recesses 26. The three first connection portions 31 are arranged side by side, and the three first nut holder holding portions 23 position the first nut holders 5 between the first connection portions 31 and the first nut holder holding portions 23. The connector portion 4 and the three first connection portions 31 are arranged side by side.

Two partition walls 24 are provided. The partition walls 24 extend from the end face of the main body portion 22 away from the flange portion 21 to the opposite side to the flange portion 21. Each of the partition walls 24 is disposed between the first nut holder holding portions 23 adjacent to each other.

The second nut holder holding portions 25 are provided on a surface of the flange portion 21 on the opposite side from the main body portion 22.

The first nut holder 5 is a member that holds the first nut 11 and is assembled to the housing 2, and is made of insulating synthetic resin. Three first nut holders 5 in total are provided, and each of the first nut holders 5 is provided for the corresponding one of the busbars 3. As illustrated in FIG. 7, the first nut holder 5 integrally includes an annular attachment portion 51 attached to the outer peripheral portion of the middle portion 33 of the busbar 3, a locking arm 52 locked to the first nut holder holding portion 23, and a nut holding portion 53 holding the first nut 11. The annular attachment portion 51 is inserted into the recess 26 to prevent the first ring-shaped seal member 13 from shifting in position.

The second nut holder 6 is a member that holds three second nuts 12 and is assembled to the housing 2, and is made of insulating synthetic resin. The second nut holder 6 integrally includes three contact portions 61 that are in contact with the flange portion 21, three retaining plate portions 62 connected to each contact portion 61, two connecting portions 63 connecting adjacent retaining plate portions 62, and two locking arms 64 connected to the respective connecting portions 63.

As illustrated in FIG. 7, the contact portion 61 positions the second nut 12 between the contact portion 61 and the second connection portion 32. The retaining plate portion 62 positions the second nut 12 between the retaining plate portion 62 and the second nut holder holding portion 25. The locking arms 64 lock into the second nut holder holding portions 25.

The current sensor-attached terminal block 1 in this example is constructed by molding the housing 2 with the busbars 3, the magnetic cores 71, and the collars 15 through insert molding and thereafter assembling the other parts. However, as long as the first ring-shaped seal members 13 and the second ring-shaped seal member 14 are provided, the busbars 3 and the magnetic cores 71 may be assembled into the housing 2 by other fixing methods other than insert molding.

The current sensor-attached terminal block 1 integrated with the terminal block and the current sensors 7 takes up less mounting space than a case where the terminal block and the current sensors 7 are separately provided, thus allowing for reduction of the e-Axle in size. In addition, due to the integration, the amount of resin used in the housing is less than in the case of separate bodies, which helps reduce costs.

It should be noted that the above-mentioned embodiment merely illustrates a representative form of the present invention, and the present invention is not limited to this embodiment. In other words, the present invention can be implemented with various modifications within the scope of the gist of the present invention. As long as the configuration of the present invention is still included in such modifications, it is to be understood that these modifications are included in the scope of the present invention.

### LIST OF REFERENCE SIGNS

1 current sensor-attached terminal block
2 housing
3 busbar
7 current sensor
8 casing
13 first ring-shaped seal member
14 second ring-shaped seal member

What is claimed is:

1. A current sensor-attached terminal block comprising:
a busbar in a plate shape;
a current sensor configured to detect a current flowing through the busbar;
a housing holding the busbar and the current sensor, and attached to an attachment hole of a casing of an electronic device;
a first ring-shaped seal member; and
a second ring-shaped seal member,
wherein a first connection portion on one end side of the busbar and a second connection portion on the other end side of the busbar are exposed outside the housing, and a middle portion of the busbar is situated inside the housing,
the first ring-shaped seal member is attached to an outer peripheral portion of the middle portion of the busbar to seal between busbar and the housing, and
the second ring-shaped seal member is attached to an outer peripheral portion of the housing to seal between the housing and the attachment hole.

2. The current sensor-attached terminal block according to claim 1, wherein the current sensor includes a magnetic core in a C shape surrounding the middle portion of the busbar, and a detection element disposed in a gap of the magnetic core.

3. The current sensor-attached terminal block according to claim 2, further comprising:
a circuit board on which the detection element is mounted,
wherein the middle portion of the busbar and the magnetic core are embedded in the housing to be integrated with the housing,
the detection element and the circuit board are accommodated in an accommodation space of the housing in a detachable manner, and
the current sensor-attached terminal block further comprises a cover that covers the accommodation space.

4. The current sensor-attached terminal block according to claim 1, wherein a bolt insertion hole is formed in each of the first connection portion and the second connection portion, and
the current sensor-attached terminal block further comprises:
a first nut placed on the first connection portion;
a first nut holder holding the first nut and being assembled with the housing;
a second nut placed on the second connection portion; and
a second nut holder holding the second nut and being assembled with the housing.
